(19) United States
(12) Patent Application Publication
(10) Pub. No.: US 2011/0042803 A1
(43) Pub. Date: Feb. 24, 2011

(54) Method For Fabricating A Through Interconnect On A Semiconductor Substrate

(76) Inventor: CHEN-FU CHU, Hsinchu City (TW)

Correspondence Address: STEPHEN A GRATTON;THE LAW OFFICE OF STEVE GRATTON, 2764 SOUTH BRAUN WAY, LAKEWOOD, CO, 80228, US

(21) Appl. No.: 12/545,949

(22) Filed: Aug. 24, 2009

(51) Int. Cl. H01L 23/498; H01L 21/768

(52) U.S. Cl. 257/737; 438/667; 438/613; 257/E21.597; 257/E21.589; 257/E23.068

(57) ABSTRACT

A method for fabricating a through interconnect on a semiconductor substrate includes the steps of forming a via on a first side of the substrate part way through the substrate, forming an electrically insulating layer on the first side and in the via, forming an electrically conductive layer at least partially lining the via, forming a first contact on the conductive layer in the via, and thinning the substrate from a second side at least to the insulating layer in the via. The method can also include the step of forming a second contact on a second side of the substrate in electrical contact with the first contact. The method can be performed on a semiconductor wafer to form a wafer scale interconnect component. In addition, the interconnect component can be used to construct semiconductor systems such as a light emitting diode (LED) systems.

### BACKGROUND

This invention relates generally to the fabrication of semiconductor components, and more particularly to a wafer level method for fabricating a through interconnect on a semiconductor substrate.

Semiconductor substrates sometimes require electrical interconnects through the substrate from the front side to the back side thereof. This type of through interconnect is sometimes referred to as a through silicon via (TSV). For example, an optoelectronic system, such as a light emitting diode (LED) display, can include a semiconductor substrate for mounting and making electrical connections to the light emitting diodes (LEDs). The LED display can include an array of from hundreds to thousands of light emitting diodes, requiring from hundreds to thousands of through interconnects in the substrate. As semiconductor substrates become smaller and more complex, it is difficult to make through interconnects using conventional fabrication techniques.

One type of through interconnect includes an electrically insulated through via extending from the front side to the back side of the substrate, which is filled, or lined, with an electrically conductive metal. A problem with fabricating this type of through interconnect is that it is difficult to fill, or line, the through via with metal, particularly with a small via on a tight pitch. Conventional fabrication techniques use plasma vapor deposition (PVD) and evaporation to fill, or line, the through vias with a metal. However, these techniques can produce poor step coverage and voids in the metal, decreasing the conductivity and increasing the resistivity of the through interconnect.

In view of the foregoing, improved fabrication processes for making through interconnects on semiconductor substrates are needed in the art. However, the foregoing examples of the related art and limitations related therewith, are intended to be illustrative and not exclusive. Other limitations of the related art will become apparent to those of skill in the art upon a reading of the specification and a study of the drawings.

### SUMMARY

A method for fabricating a through interconnect on a semiconductor substrate includes the steps of forming a via on a first side of the substrate part way through the substrate, forming an electrically insulating layer on the first side and in the via, forming an electrically conductive layer on the insulating layer at least partially lining the via, forming a first contact on the conductive layer in the via, and then thinning the substrate from a second side of the substrate at least to the insulating layer in the via. The method can also include the step of forming a second contact on the second side of the substrate in electrical contact with the first contact.

An interconnect component formed by the method includes a semiconductor substrate and a plurality of through interconnects in the substrate. Each through interconnect includes a via through the semiconductor substrate, a front side contact within the via, and a back side contact in electrical contact with the front side contact.

### BRIEF DESCRIPTION OF THE DRAWINGS

Exemplary embodiments are illustrated in the referenced figures of the drawings. It is intended that the embodiments and the figures disclosed herein are to be considered illustrative rather than limiting.

FIGS. 1A-1L are schematic cross sectional views illustrating steps in a method for fabricating through interconnects on a semiconductor substrate;

FIGS. 2A-2E are schematic cross sectional views equivalent to FIGS. 1H-1L illustrating alternate steps of the method of FIGS. 1A-1L in place of FIGS. 1H-1L;

FIGS. 3A-3C are schematic cross sectional view equivalent to FIGS. 1J-1L illustrating alternate steps of the method of FIGS. 1A-1L in place of FIGS. 1J-1L;

FIGS. 4A-4C are schematic cross sectional views equivalent to FIGS. 1J-1L illustrating alternate steps of the method of FIGS. 1A-1L in place of FIGS. 1J-1L;

FIG. 5 is a schematic cross sectional view equivalent to FIG. 1L illustrating an alternate embodiment through interconnect; and

FIG. 6 is a schematic cross sectional view illustrating a reflow oven for fabricating the through interconnect of FIG. 5.

### DETAILED DESCRIPTION

As used herein, “semiconductor component” means an electronic element that includes a semiconductor substrate. “Wafer-level” means a process conducted on a semiconductor wafer. “Wafer scale” means having an outline about the same as that of a semiconductor wafer.

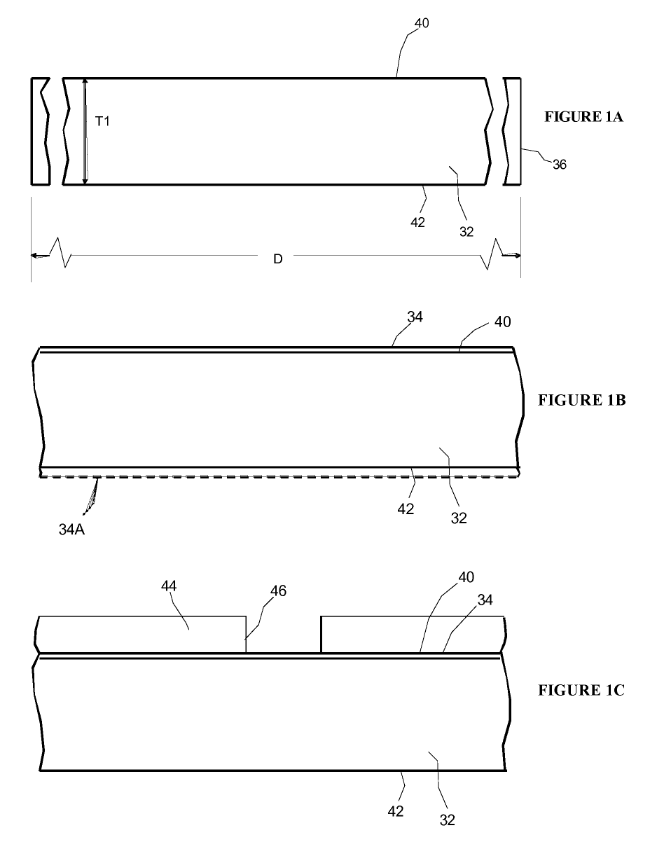

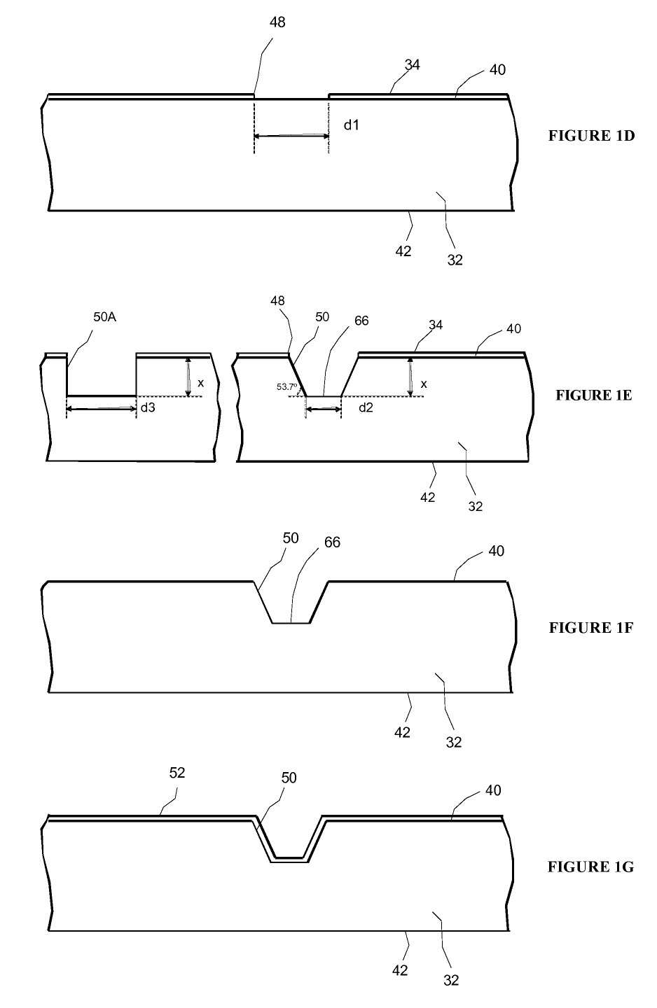

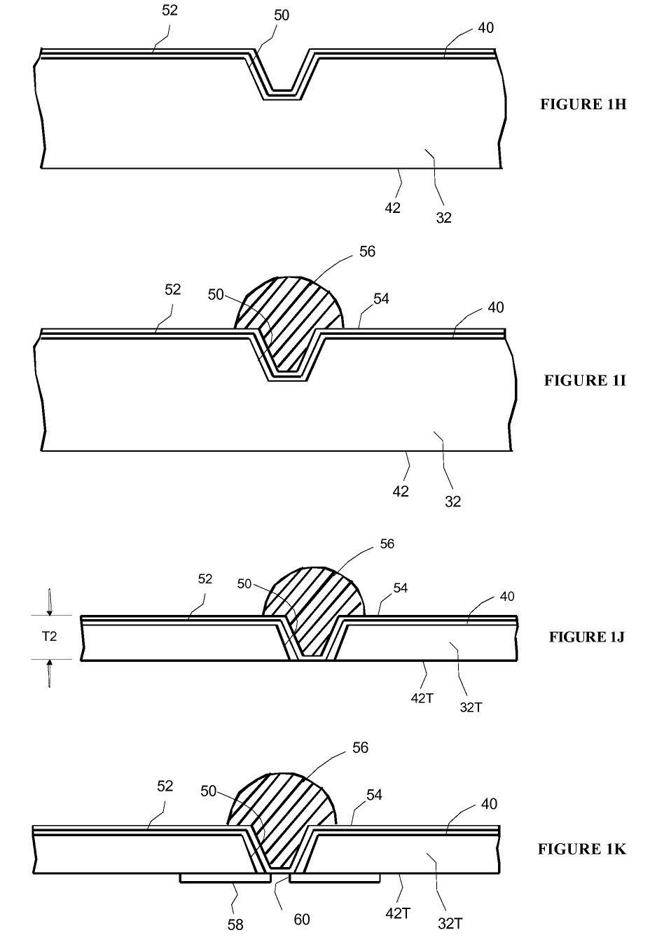

Referring to FIGS. 1A-1L, steps in a method for fabricating a through interconnect 30 (FIG. 1L) on a semiconductor substrate 32 are illustrated. Although for illustrative purposes the steps of the method are shown in a particular order, the method can be practiced with a different order. Initially, as shown in FIG. 1A, the semiconductor substrate 32 can be provided. The semiconductor substrate 32 includes a front side 40 and a back side 42. In the claims to follow the front side 40 is sometimes referred to as the “first side”, and the back side 42 is sometimes referred to as the “second side”.

As shown in FIG. 1A, the semiconductor substrate 32 can comprise a semiconductor wafer 36 having a standard diameter D of from 50-450 mm, and a full thickness T1 of from about 50-1000 μm. The semiconductor wafer 36 permits standard wafer fabrication equipment to be used to perform a wafer level method, and produces a wafer scale interconnect component 38 (FIG. 1L). By way of example, a 150 mm diameter wafer has a full thickness (T1) of about 675 μm, a 200 mm diameter wafer has a full thickness (T1) of about 725 μm, and a 300 mm diameter wafer has a full thickness (T1) of about 775 μm. In the illustrative embodiment, the semiconductor wafer 36 and the semiconductor substrate 32 comprise silicon (Si). However, the semiconductor wafer 36 and the semiconductor substrate 32 can comprise another material such GaAs, SiC, AlN, Al₂O₃, or sapphire.

Next, as shown in FIG. 1B, a hard mask layer 34 can be formed on the front side 40 of the semiconductor substrate 32. The hard mask layer 34 can comprise a conventional hard mask material, such as Si₃N₄, SiO₂, Al₂O₃, Ta₂O₅, or TiO₂ which can be deposited using ALD, CVD, PECVD, PVD or evaporation. The hard mask layer 34 can also be grown on the semiconductor substrate 32 using an oxidation or nitridation process, such as thermal oxidation of a Si substrate using wet or dry oxidation (e.g., H₂O, O₂, O₃, NOx). A representative thickness of the hard mask layer 34 can be from 100-10,000 Å. The hard mask layer 34 can also comprise multiple layers of different materials. In the illustrative embodiment, the hard mask layer 34 can comprise SiO₂ and/or SiN₄. Optionally, as indicated by the dotted lines in FIG. 1B, a back side hard mask layer 34A can also be formed on the back side 42 at the same time that the hard mask layer 34 is formed.

Next, as shown in FIG. 1C, a layer of resist can be formed on the front side 40 of the semiconductor substrate 32, and a photolithographic process can be used to form a photomask 44 having a pattern of openings 46 with a desired size and shape. As shown in FIG. 1D, the openings 46 can be used to etch corresponding openings 48 in the hard mask layer 34 using a suitable wet or dry etch process. For example, for a SiO₂ hard mask layer 34, the etch process can be performed with a wet etchant such as HF acid, or a dry etch process performed with a fluorine or chlorine etching species, such as CF₄:O₂ or CHF₃:O₂. The openings 46 can have any desired size and shape, such as circular, rectangular, square, or elliptical, with a size (e.g., diameter d1) of from 1-2000 μm. As also shown in FIG. 1D, following formation of the openings 46, the photomask 44 can be removed using a suitable stripping process.

Next, as shown in FIG. 1E, a via forming step can be performed using the hard mask layer 34 and a suitable process, such as wet or dry etching, to form vias 50 in the semiconductor substrate 32. The via forming step can be endpointed to form the vias 50 on the front side 40 part way through the semiconductor substrate 32, with a depth x of from 1-500 μm from the front side 40 being representative. By way of example, the vias 50 can be formed using a crystalgraphic etch process performed using a wet etchant, such as a solution of KOH (44%) or TMAH (25%). This wet etchant could be used to etch <100> Si at approximately 1 μm/min, while etching Si₃N₄ at <1 Å/min and SiO2 at <20 Å/min, while <111> Si is etched at a much slower rate (i.e., 1/100 of <100> Si). An isotropic etch process can be performed using a solution of HF, HNO₃ CH₃COOH and H₂O. As illustrated in FIG. 1E, with a crystalgraphic etch process, the vias 50 will be preferentially etched, with the sidewalls of the vias 50 sloped at an angle of about 53.7 degrees from horizontal (i.e., a line parallel to the plane of the front side 40). In addition, the vias 50 can include a planar bottom surface 66 having a desired diameter d2 (e.g., 1-500 μm), which is dependent on the size of the openings 48 in the hard mask layer 34, and on the etch time. Rather than wet etching, the vias 50 can be formed using a dry etch process, such as BOSCH etch. As also shown in FIG. 1E, if a crystalgraphic etch process is not performed a via 50A can have a depth x, a width d3, and sidewalls which are generally perpendicular to the front side 40 of the semiconductor substrate 32.

Next, as shown in FIG. 1F, the optional step of removing the hard mask layer 34 is shown. The hard mask layer 34 can be removed using a suitable process, such as an etching or stripping process, using a wet or dry etchant. Following this step, the semiconductor substrate 32 includes a plurality of vias 50 on the front side 40 which extend only part way through the substrate 32 to the depth x (FIG. 1E).

Next, as shown in FIG. 1G, an insulating layer forming step can be performed to form an electrically insulating isolation layer 52 on the front side 40 of the semiconductor substrate 32, and on the sidewalls of the vias 50. The isolation layer 52 preferably has a small thickness (e.g., bg 100 Å to 1 μm), such that the vias 50 remain open. The isolation layer 52 can comprise an electrically insulating material, such as an oxide (e.g., SiO₂) or a nitride (e.g., Si₃N₄), that can be either grown in place, or deposited using a suitable deposition process, such as CVD, PECVD, or ALD. Other suitable dielectric layers include Al₂O₃, Ta₂O₅ and titanium oxide deposited using a suitable process. SiO2 could also be thermally grown using steam or a dry oxidation process. As another alternative, the isolation layer 52 can comprise a polymer material, such as polyimide, that can be deposited on the front side 40 and into the vias 50 using a suitable process such as deposition through a nozzle, or electrophoresis. As yet another alternative, the isolation layer 52 can comprise a polymer such as parylene, that can be vapor deposited on the front side 40 and into the vias 50 using CVD.

Next, as shown in FIG. 1H, a conductive layer forming step can be performed to form an electrically conductive metallization layer 54 on the isolation layer 52. The metallization layer 54 can comprise a single layer of a highly conductive metal such as Ti, Ta, Cu, W, TiW, Hf, Ag, Au, or Ni deposited using sputtering, PVD, CVD, evaporation or electroless chemical deposition. However, rather than a single layer of material, the metallization layer 54 can comprise a multi-metal stack, such as a bi-metal stack comprised of a conductive layer and a bonding layer (e.g., Cu/Ni), or multi layers such a Ta/TaN/Cu/Ni/Au and alloys of these metals. The metallization layer 54 can be formed using a suitable deposition process (i.e., additive process) such as PVD, electroless deposition, electroplating or PVD through a mask (not shown). As another example, the metallization layer 54 can be formed by blanket deposition of a metal layer followed by etching through a mask (i.e., subtractive process). Due to the aspect ratio of the via 50, the step coverage of the metallization layer 54 will typically be less than 100%.

In the illustrative embodiment, the conductive layer forming step can be performed to form the metallization layer 54 with a thickness that does not completely fill the vias 50. In particular, the metallization layer 54 lines the sidewalls of the vias 50 rather than fills the vias 50.

Next, as shown in FIG. 1I, a front side contact forming step can be performed to form front side contacts 56 in the vias 50, and on the front side 40 of the substrate 32 circumjacent to the vias. In the claims to follow the front side contacts 56 are sometimes referred to as the “first contacts”. The front side contacts 56 can comprise metal (e.g., solder, nickel), balls, bumps or pins, formed on the metallization layer 54 using deposition of a flowable metal into the vias 50. For example, a flowable metal, such as solder or metal paste, can be deposited, or screen printed through a mask, to fill the vias 50 and form the front side contacts 56 as metal bumps. The front side contacts 56 can also be formed using a ball bonding process or a stud bumping process. The front side contacts 56 can also be formed using a two step process wherein the vias 50 are filled by deposition or screen printing, followed by a bump (or ball) forming step.

Many other techniques could also be used to form the front side contact 56. For example, solder bump bonding (SBB) uses solder wire in a modified wire bonder to place a ball of solder directly onto a bond pad. The scrubbing action of the wire bonder causes the solder ball to bond to the bond pad. The solder wire is broken off above the bump, leaving the bump on the pad, where it can be reflowed. Solder bump bonding is a serial process, producing bumps one by one at rates up to about 8 per second. It has advantages in allowing closer spacing than printed bumps. Another technique is solder jetting, which places solder bumps on Ni—Au under bump metallization (UBM) by controlling a stream of droplets of molten solder. As another example, demand mode jetting systems use piezoelectrics or resistive heating to form droplets in much the same manner as an ink-jet printer. Mechanical positioning directs the droplet placement. Continuous mode jetting systems use a continuous stream of solder droplets with electrostatic deflection of the charged droplets to control placement.

In the illustrative embodiment, the front side contacts 56 comprise metal bumps formed of a bondable metal such as solder (e.g., SnPd, SnAg, SnCu, SnAgCu, NiSnAgCu, AuSn). The metallization layer 54 can comprise a metal, such as copper, which attracts and provides adhesion for filling the vias 50. A representative range for the diameter of the front side contacts 56 can be from 1-1000 μm.

Next, as shown in FIG. 1J, a thinning step can be performed from the back side 42 to thin the semiconductor substrate 32 and form a thinned semiconductor substrate 32T having a thinned back side 42T. The thinning step can be endpointed at the isolation layer 52. However, the thinning step is preferably performed to remove the isolation layer 52 at the bottom surface of the via 50 and to expose the metallization layer 54 in the via 50. The thinning step can be performed using a mechanical planarization process performed with a mechanical planarization apparatus, such as a grinder. This type of mechanical planarization process is sometimes referred to as dry polishing. One suitable mechanical planarization apparatus is manufactured by Okamoto, and is designated a model no. VG502. The thinning step can also be performed using a chemical mechanical planarization (CMP) apparatus. Suitable chemical mechanical planarization (CMP) apparatus are commercially available from manufacturers such as Westech, SEZ, Plasma Polishing Systems, and TRUSI. The thinning step can also be performed using an etch back process, such as a wet etch process, a dry etch process or a plasma etching process either performed alone or in combination with mechanical planarization. The thinning step can also be performed using a multi step process such as back grinding, followed by a soft polish step, then CMP and a cleaning step. As another alternative, a polishing step could be used to expose the isolation layer 52, the isolation layer 52 could be etched to expose the metallization layer 54.

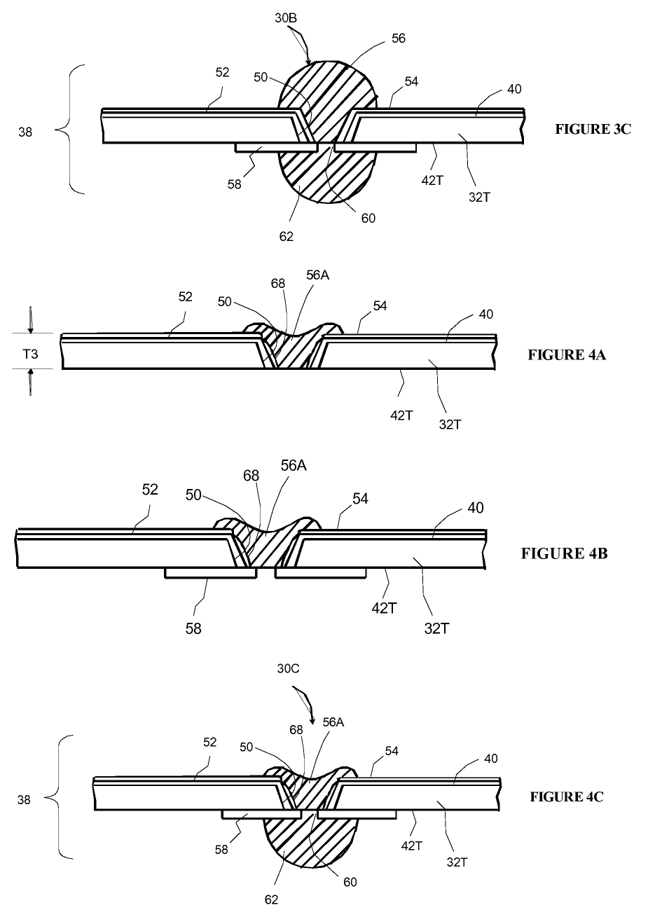

The thickness T2 (FIG. 1J) of the thinned substrate 32T can be selected as desired, with from 35 μm to 300 μm being representative. The thinned back side 42T has a smooth, polished surface, and is devoid of features. As shown in FIG. 3A, with endpointing of the thinning step into the front side contact 56 in the via 50, a thickness T3 of the thinned semiconductor substrate 32T will be less than the thickness T2 (FIG. 1J) by at least the thickness of the metallization layer 54 that has been removed.

Next, as shown in FIG. 1K, a back side insulating layer forming step can be performed to form an electrically insulating back side isolation layer 58 on the thinned back side 42T having openings 60 aligned with the exposed metallization layer 54 in the vias 50. The backside isolation layer 58 can completely cover the exposed isolation layer 50 on the sidewalls of the vias 50 as shown, or can only partially cover the exposed isolation layer 50. The backside isolation layer 58 can comprise an electrically insulating material, such as an oxide (e.g., SiO₂), a nitride (e.g., Si₃N₄), or a polymer (e.g., polyimide, parylene) formed using a suitable process, substantially as previously described for the front side isolation layer 52.

Next, as shown in FIG. 1L, a back side contact forming step can be performed to form back side contacts 62 on the thinned back side 42T, and in the openings 60 aligned with the exposed metallization layer 54 in the vias 50. In the claims to follow the back side contacts 62 are sometimes referred to as the “second contacts”. The back side contacts 62 can comprise metal, or solder, balls, bumps or pins, formed on the exposed metallization layer 54 in the vias 50 using a metallization process, such as deposition or screen printing through a mask, substantially as previously described for the front side contacts 56. The back side contacts 62 can also be formed using a stud bumping process or a ball bonding process substantially as previously described for front side contacts 56. In the illustrative embodiment, the back side contacts 62 comprise metal bumps formed of a bondable metal such as solder (e.g., SnPd, SnAg, SnCu, SnAgCu, NiSnAgCu, AuSn). A representative range for the diameter of the back side contacts 62 can be from 60-950 μm.

As shown in FIG. 1L, each through interconnect 30 includes a via 50 through the thinned semiconductor substrate 32T, a front side contact 56 within the via 50, and a back side contact 62 in electrical contact with the front side contact 56. In addition, the metallization layer 54 within the via 50 electrically connects the front side contact 56 to the back side contact 62.

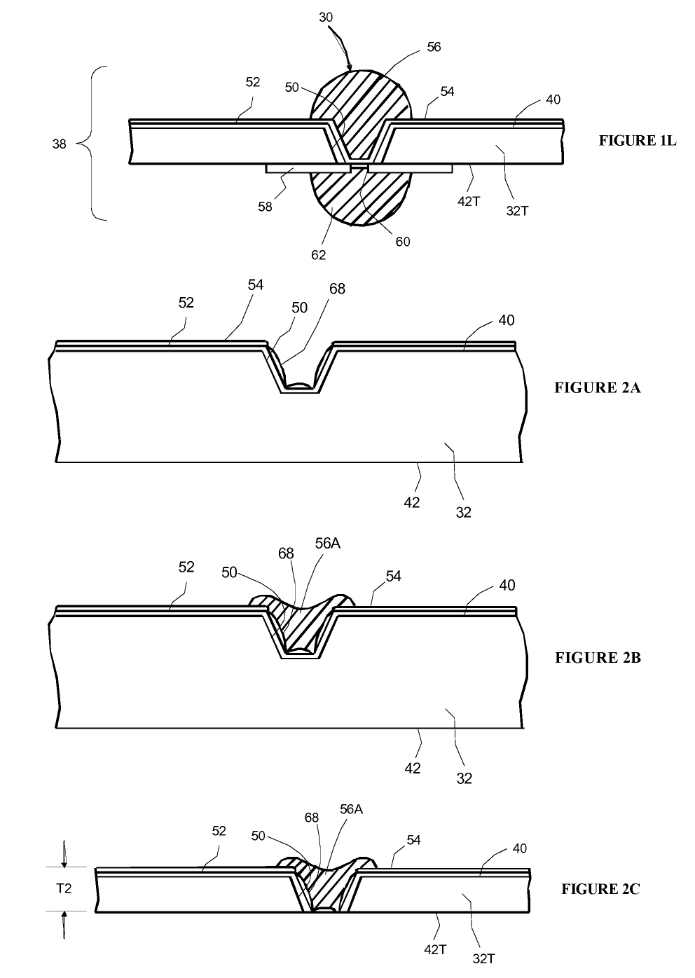

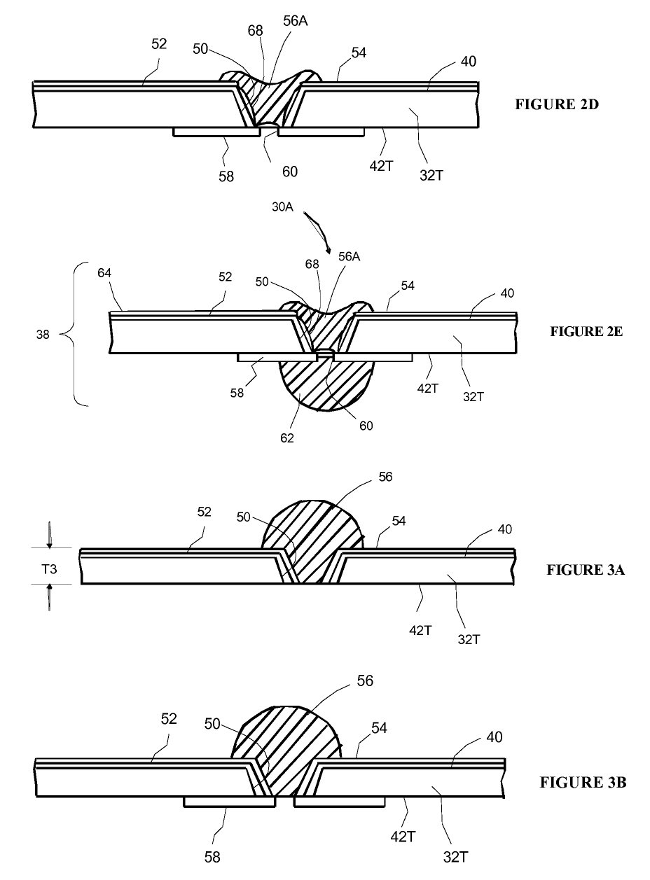

Referring to FIGS. 2A-2E, alternate steps of the method are illustrated. FIG. 2A is substantially similar to the conductive layer forming step previously shown and described in FIG. 1H. However, in this embodiment the metallization layer 54 does not have 100% step coverage in the via 50, such that a stepped metallization layer 68 is formed in the via 50. As shown in FIG. 2B, a front contact forming step forms a front contact 56A which fills the via 50 in electrical contact with the stepped metallization layer 54, but as a concave pad rather an elevated bump on the front side 40 of the substrate 32 as with front contact 56 (FIG. 1I). The front contact 56A can be made using a reflow process wherein a flowable metal is reflowed into the via 50 with a concave surface topography using a reflow oven 70 (FIG. 6). Alternately, the front contact 56A can be made by removing excess material from the bumped front contact 56 (FIG. 1I) by chemical or mechanical polishing, substantially as previously described for the thinning step. FIG. 2C illustrates a thinning step for forming the thinned semiconductor substrate 32T, substantially as previously shown and described in FIG. 1J. FIG. 2D illustrates a back side insulating layer forming step for forming the back side isolation layer 58, substantially as previously shown and described in FIG. 1K. FIG. 2E illustrates a back side contact forming step for forming the back side contact 62, substantially as previously shown and described in FIG. 1L. As shown in FIG. 2E, a through interconnect 30A is substantially similar to the previously described through interconnect 30 (FIG. 1L), but with the front contact 56A having a concave surface rather than a bump.

Referring to FIGS. 3A-3C, alternate steps of the method are illustrated. FIG. 3A shows a thinning step substantially similar to the thinning step previously shown and described in FIG. 1J. However, in this embodiment, the thinning step can be endpointed to at least partially contact the material of the front side contact 56 in the via 50. As shown in FIG. 3B, with endpointing of the thinning step into the front side contact 56 in the via 50, the back side isolation layer 58 can also cover portions of the metallization layer 54 in the via 50, while leaving at least a portion of the front side contact 56 as exposed. As shown in FIG. 3C, with endpointing of the thinning step into the front side contact 56 in the via 50, each through interconnect 30B is substantially similar to the previously described through interconnect 30 (FIG. 1L), but with the metallization layer 54 on the bottom surface 66 (FIG. 1E) of the via 50 removed.

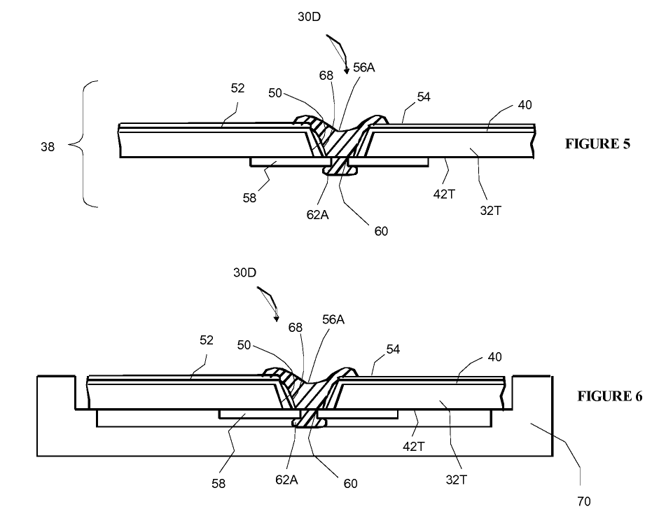

Referring to FIGS. 4A-4C, alternate steps of the method are illustrated. FIG. 4A shows a thinning step substantially similar to the thinning step previously shown and described in FIG. 2C. However, in this embodiment, the thinning step can be endpointed to at least partially contact the material of the front side contact 56A in the via 50. As shown in FIG. 4B, with endpointing of the thinning step into the front side contact 56A in the via 50, the back side isolation layer 58 can also cover portions of the stepped metallization layer 68 in the via 50, while leaving at least a portion of the front side contact 56A as exposed. As shown in FIG. 4C, with endpointing of the thinning step into the front side contact 56A in the via 50, each through interconnect 30C is substantially similar to the previously described through interconnect 30A (FIG. 2E), but with the stepped metallization layer 68 on the bottom surface 66 (FIG. 1E) of the via 50 removed.

As shown in FIG. 5, a through interconnect 30D can be substantially similar to the previously described through interconnect 30C (FIG. 4C). However, the through interconnect 30D includes a back side contact 62A which comprises a pad, rather than a bump as with back side contact 62 (FIG. 4C). The back side contact 62A can be made using a reflow process in a reflow oven 70 (FIG. 6), substantially as previously described for front side contact 56A (FIG. 2B). Alternately, the back side contact 62A can be made by removing excess material from the bumped back side contact 62 (FIG. 4C) by chemical or mechanical polishing, substantially as previously described for front side contact 56A (FIG. 2B).

Thus the disclosure describes an improved method for fabricating through interconnects for semiconductor substrates and an improved wafer scale interconnect component. While a number of exemplary aspects and embodiments have been discussed above, those of skill in the art will recognize certain modifications, permutations, additions and subcombinations thereof. It is therefore intended that the following appended claims and claims hereafter introduced are interpreted to include all such modifications, permutations, additions and sub-combinations as are within their true spirit and scope.

What is claimed is:

1. A method for fabricating a through interconnect on a semiconductor substrate comprising:
forming a via in a first side of the substrate part way through the substrate;
forming an electrically insulating layer on the first side and in the via;
forming a conductive layer on the insulating layer at least partially lining the via;
forming a first contact on the first side of the substrate comprising a flowable metal filling the via in electrical contact with the conductive layer; and
thinning a second side of the substrate at least to the insulating layer.

2. The method of claim 1 further comprising forming a second contact on the second side of the substrate in electrical contact with the first contact.

3. The method of claim 1 wherein the conductive layer comprises a metallization layer and the first contact comprises a bump or a pad.

4. The method of claim 1 wherein the thinning step comprises a method selected from the group consisting of grinding, chemical mechanical planarization, and etching.

5. The method of claim 1 wherein the forming the first contact step comprises deposition of solder or metal paste through a mask.

6. The method of claim 1 wherein the forming the first contact step comprises a solder bump bonding (SBB) process or a solder jetting process.

7. The method of claim 1 wherein the forming the first contact step comprises a two step process wherein the via is filled by deposition of the flowable metal, followed by a bump or ball forming step.

8. The method of claim 1 wherein the forming the first contact step comprises reflow of the flowable metal into the via using a reflow oven.

9. The method of claim 1 wherein the via includes a bottom surface and the thinning step is performed to remove at least a portion of the conductive layer on the bottom surface.

10. The method of claim 1 wherein the via includes a bottom surface and the thinning step is performed to leave at least a portion of the conductive layer on the bottom surface.

11. A method for fabricating a through interconnect on a semiconductor substrate comprising:
providing the semiconductor substrate with a first side and a second side;
forming a via in the first side having sidewalls and a bottom surface in the substrate;
forming an electrically insulating layer on the first side, on the sidewalls and on the bottom surface of the via;
forming an electrically conductive layer on the insulating layer;
forming a first contact in the via in electrical contact with the conductive layer; and
thinning the substrate from the second side at least to the insulating layer on the bottom surface of the via.

12. The method of claim 11 further comprising forming a second contact on the second side in electrical contact with the first metal bump.

13. The method of claim 12 wherein the first contact and the second contact comprise metal bumps.

14. The method of claim 12 wherein the first contact and the second contact comprise pads.

15. The method of claim 11 wherein the forming the first contact step comprises a method selected from the group consisting of deposition through a mask, stud bumping ball bonding and solder jetting.

16. The method of claim 11 wherein the forming the via step comprises crystalgraphic etching and the via has sloped sidewalls.

17. The method of claim 11 wherein the thinning step comprises a method selected from the group consisting of grinding, chemical mechanical planarization, and etching.

18. A method for fabricating a plurality of through interconnects on a semiconductor substrate comprising:
providing a semiconductor wafer having a first side and a second side;
forming a hard mask on the first side having a plurality of openings;
etching a plurality of vias aligned with the openings part way through the substrate;
forming an electrically insulating layer on the first side and in the vias;
forming a metallization layer on the insulating layer at least partially lining the vias;
forming a plurality of first contacts on the first side filling the vias in electrical contact with the metallization layer lining the vias; and
thinning the wafer from the second side to expose the metallization layer or the first contacts in the vias.

19. The method of claim 18 further comprising forming a plurality of second contacts on the second side in electrical contact with the first contacts.

20. The method of claim 18 wherein the first contacts comprise solder or metal paste deposited into the vias.

21. The method of claim 18 wherein the forming the first contacts step comprises reflowing a metal of the first contacts into the vias using a reflow oven.

22. The method of claim 18 wherein the forming the first contacts step comprises a solder bump bonding (SBB) process or a solder jetting process.

23. The method of claim 18 wherein the forming the first contacts step comprises a two step process wherein the vias are filled by deposition of a flowable metal, followed by a bump or ball forming step.

24. An interconnect component comprising:
a thinned semiconductor substrate having a first side and a second side;
a via through the thinned semiconductor substrate from the first side to the second side;
a first electrically insulating layer on the first side and in the via;
a metallization layer on the first electrically insulating layer at least partially lining the via;
a first contact comprising a first metal bump on the first side and within the via in electrical contact with the metallization layer;
a second electrically insulating layer on the second side; and
a second contact comprising a second metal bump on the second electrically insulating layer in electrical contact with the first contact in the via.

25. The interconnect of claim 24 wherein the first metal bump and the second metal bump comprise solder.

26. The interconnect of claim 24 wherein the via includes sidewalls and a bottom surface, and the under bump metallization layer is on the sidewalls and the bottom surface.

27. The interconnect of claim 24 wherein the via includes sidewalls and a bottom surface, and the under bump metallization layer is on the sidewalls but not on the bottom surface.
